(19) United States
(12) Patent Application Publication
(10) Pub. No.: US 2009/0085640 A1
(43) Pub. Date: Apr. 2, 2009

(54) Level shift device and method for the same

(75) Inventor: Yi-Lin Chen, Hsinchu (TW)

Correspondence Address: TUNG & ASSOCIATES, Suite 120, 838 W. Long Lake Road, Bloomfield Hills, MI, 48302, US

(73) Assignee: Realtek Semiconductor Corp.

(21) Appl. No.: 12/284,825

(22) Filed: Sep. 25, 2008

(30) Foreign Application Priority Data
Sep. 27, 2007 (TW) TW096135843

(51) Int. Cl. H03L 5/00

(52) U.S. Cl. 327/333

(57) ABSTRACT

The present invention discloses a level shift device which comprises: a level shift circuit for receiving an input with a first voltage level and generating a first signal and a second signal with a second voltage level; and an output circuit which generates an output according to the first signal and the second signal.

### BACKGROUND OF THE INVENTION

1. Field of the Invention

The present invention relates to a level shift device, and in particular to a level shift device capable of providing about the same positive and negative duty cycles, and a method for the same.

2. Description of the Related Art

To reduce power consumption, it is a trend to decrease the operational voltage within a circuit chip to, e.g., 1.2V or lower, but the communication between circuit chips operates in a higher voltage such as 3.3V. For this reason, a level shift device is required as an input/output interface circuit to shift the operational level within a circuit chip to a higher level for inter-chip communication. FIG. 1 shows the basic structure of a conventional level shift circuit 10, which comprises two PMOS transistors M1 and M2, and two NMOS transistors M3 and M4. Assuming the function of the circuit is to convert the voltage level from 1.2V to 3.3V, the input IN in the shown circuit may thus be an operational voltage of 1.2V (the first operational voltage), and the voltage supplied from the voltage source VP2 may be 3.3V (the second operational voltage).

Referring to FIGS. 1 and 2, the conventional level shift circuit operates as follows. At time T0, the initial state of the circuit, the input IN is at the low level of the first operational voltage (e.g., 0V), while the inverted input INB is at the high level of the first operational voltage (e.g., 1.2V). Because the inverted input INB is at the high level, the NMOS transistor M4 is ON, whereby the node B is grounded through the NMOS transistor M4 and is at the low level of 0V. The voltage level of the node B is exactly the voltage level of the output OUT, which is thus also at the low level of 0V (the low level of the second operational voltage). Because the node B is low, the PMOS transistor M1 is ON, whereby the voltage VP2 reaches the node A through the PMOS transistor M1 so that the node A is at a high level equivalent to VP2 (the high level of the second operational voltage, such as 3.3V). Because the node A is high, the PMOS transistor M2 is OFF; the voltage VP2 does not affect the voltage level at the output OUT.

When it is desired for the circuit to generate a high voltage level output, as shown at time T1 in FIG. 2, the input IN switches from low to high, whereby the NMOS transistor M3 turns ON so that the node A is grounded through NMOS transistor M3. However, during the transition state, the PMOS transistor M1 is still partially conductive, and therefore the voltage VP2 still affects the node A; the voltage at the node A does not reach low instantly, but rather drops slowly. The PMOS transistor M2 is controlled by the node A and thus gradually turns ON until time T2. At time T2, the PMOS transistor M2 fully turns ON, and from this time on the voltage VP2 completely passes through the PMOS transistor M2 and reaches the node B so that the output OUT is pulled high to a level equivalent to VP2. In the meantime, since the node B is high, the PMOS transistor M1 fully turns OFF to stabilize node A at the low level of 0V.

FIG. 2 shows ideal waveforms under an assumption that the PMOS and NMOS transistors in each of the PMOS-NMOS transistor pairs M1 and M3, M2 and M4 have about the same driving strength. However, to ensure that the NMOS transistors M3 and M4 can over-drive the PMOS transistors M1 and M2 during the transition from low level to high level, in particular to cope with the situation where the NMOS transistors are in their worst case and the PMOS transistors are in their best case, the width of the NMOS transistors are typically made longer to increase their driving strength. Hence the driving strength of the PMOS transistor M1 is weaker than that of the NMOS transistor M3, and the driving strength of the PMOS transistor M2 is weaker than that of the NMOS transistor M4, resulting in the waveforms shown in FIG. 3, wherein the output signal of the level shift device is far slower in switching from low to high than from high to low, as referring to the time points T2, T3, T4 and T5.

Referring to FIG. 4, when the switching time from low to high and the time from high to low are not comparable, the positive (high level) and negative duty cycles (low level) are not equal to each other (TL>TH, in other words, the rising and falling time of a signal are different). If such a level shift device is used in a product wherein both the rising and falling edges of a signal are meaningful, such as a DDR DRAM or other similar products, the uneven positive and negative duty cycles will significantly impact the accuracy of the clock, data, data strobe and other signals. To ensure the accuracy of such the signals, the processing time of the signals such as the set-up time and the hold time has to be prolonged, degrading the performance of the product.

In view of the above, a level shift device providing about the same positive and negative duty cycles is desired.

### SUMMARY OF THE INVENTION

A first objective of the present invention is to provide a level shift device capable of providing about the same positive and negative duty cycles.

A second objective of the present invention is to provide a level shift method.

To achieve the foregoing objectives, according to an aspect of the present invention, a level shift device comprises: a first level shift circuit for converting an input signal with a first voltage level to a first signal and a second signal with a second voltage level, wherein the first voltage level is different from the second voltage level, and the first signal and the second signal are substantially opposite in phase, and an output stage circuit for generating an output signal according to the relationship between the first signal and the second signal.

In the above-mentioned level shift device, the output stage circuit for example can be a comparator or a second level shift circuit.

According to another aspect of the present invention, a level shift method comprises: receiving an input signal with a first voltage level; converting the input signal to a first signal and a second signal with a second voltage level, wherein the first voltage level is different from the second voltage level, and the first signal and the second signal are substantially opposite in phase, and generating an output signal according to the relationship between the first signal and the second signal.

Preferably, in the above-mentioned circuit and method, the output signal is high when the voltage level of the signal with the second voltage level is higher than the voltage level of the inverted signal of the second operational voltage, and the output signal is low when the voltage level of the inverted signal of the second operational voltage is higher than the voltage level of the signal of the second operational voltage.

For better understanding the objects, characteristics, and effects of the present invention, the present invention will be described below in detail by illustrative embodiments with reference to the attached drawings.

### BRIEF DESCRIPTION OF THE DRAWINGS

FIG. 1 is a circuit diagram schematically showing a conventional level shift circuit.

FIG. 2 is a time diagram showing the voltage level transition at the critical nodes in the conventional level shift circuit shown in FIG. 1.

FIGS. 3 and 4 explain the drawback in the prior art.

FIG. 5 is a circuit diagram schematically showing a level shift device according to a first preferred embodiment of the present invention.

FIG. 6 is a time diagram showing the voltage level transition at the critical nodes in the level shift device shown in FIG. 5.

FIG. 7 is a circuit diagram schematically showing a level shift device according to a second preferred embodiment of the present invention.

FIG. 8 is a time diagram showing the voltage level transition at the critical nodes in the level shift device shown in FIG. 7.

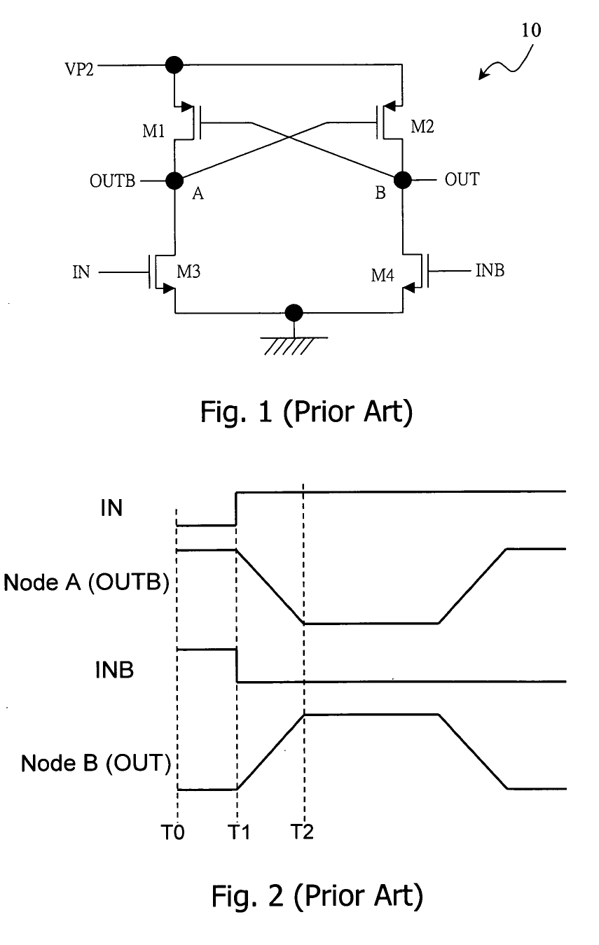

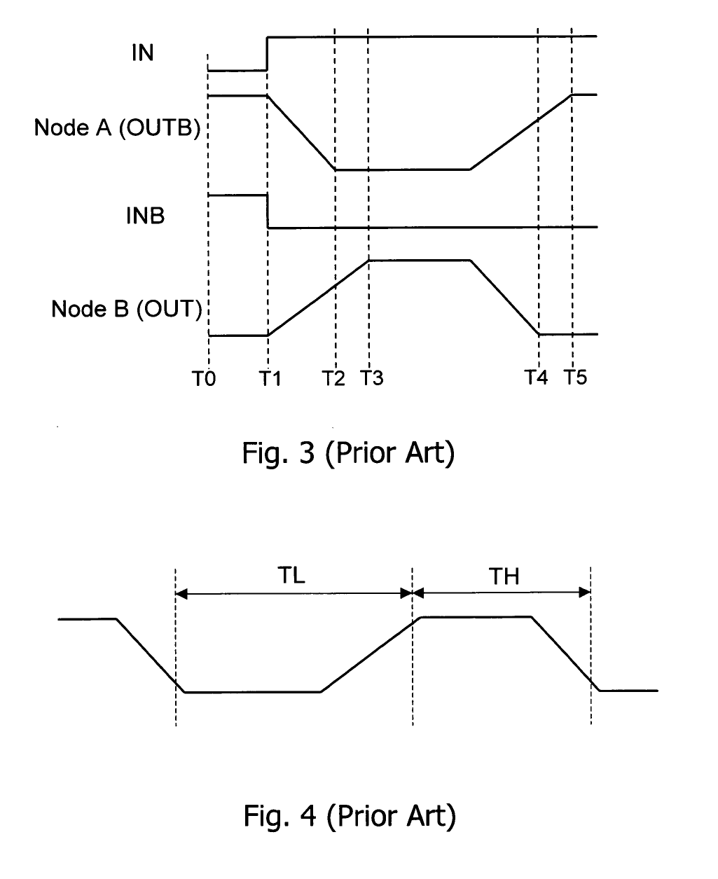

### DESCRIPTION OF THE PREFERRED EMBODIMENTS

For purpose of simplicity, in all of the following embodiments, it is assumed that the first operational voltage has a high level of 1.2V and low level of 0V, and the second operational voltage VP2 has a high level of 3.3V and a low level of 0V. The input and output signals are, e.g., clock signals. However, the present invention should not be limited as such, but may be applied to level shift between any two voltage levels and any other forms of signals.

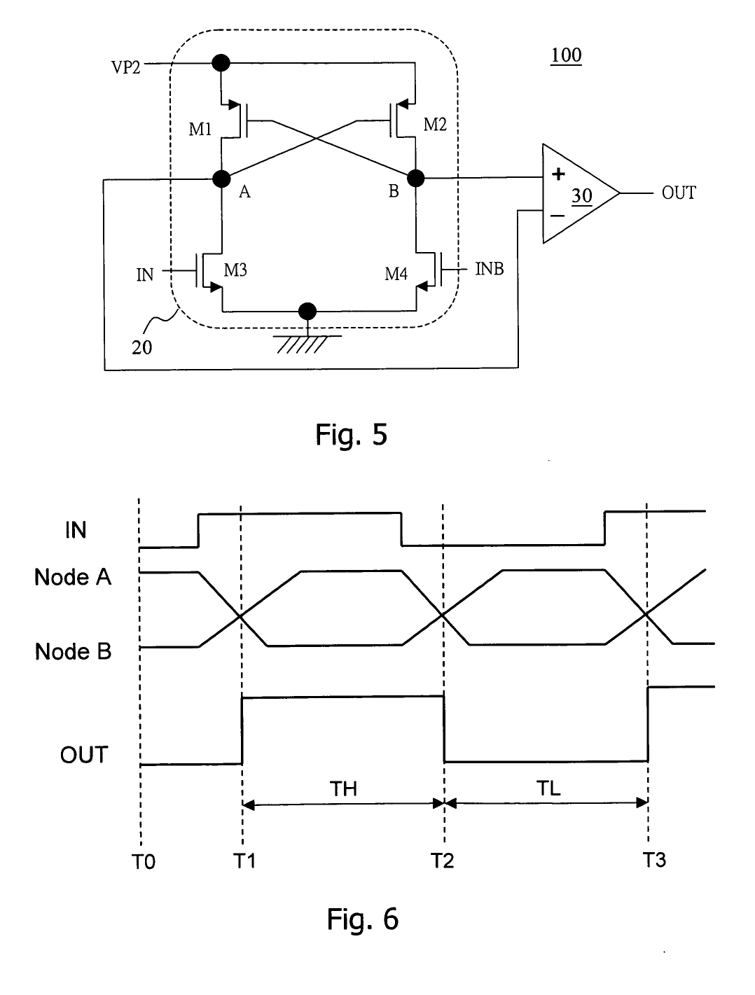

FIG. 5 schematically shows a first preferred embodiment according to the present invention. As shown in the figure, the level shift device 100 comprises a pair of PMOS transistors M1 and M2, and a pair of NMOS transistors M3 and M4 (the PMOS and NMOS pairs constituting a basic level shift circuit 20). In addition to the above, the level shift device 100 according to this embodiment further comprises an output stage circuit which determines the level of the output OUT according to the difference between the voltages at the nodes A and B. The voltage signal at the node B is an inverted signal of that at the node A; there is 180° phase difference between the signals at the nodes A and B. There are various ways to embody the output stage circuit; in this embodiment, the output stage circuit is a comparator 30.

Referring to FIG. 6 in conjunction with FIG. 5, when the input IN switches from low (0V) to high (1.2V), the voltage at the node A rapidly drops, and the voltage at the node B slowly increases. However, the output OUT of the overall circuit is not from the node B, but from the output of the comparator 30 which compares the voltages at the node A and node B; thus, the output OUT does not switch to high (3.3V) until the voltage at the node B is higher than that at the node A, as referring to time T1.

Likely, when the input IN switches from high to low, the output OUT does not switch to low until the voltage at the node B is lower than that at the node A, as referring to time T2.

Thus, as seen from FIG. 6, the positive and negative duty cycles of the output OUT are the same, i.e., TH=TL, achieving the objectives of the present invention.

One important feature of the present invention is that the output OUT of the overall circuit is generated according to the relationship between the voltages at the node A and node B. This can be embodied by many other ways than the comparator 30 described above.

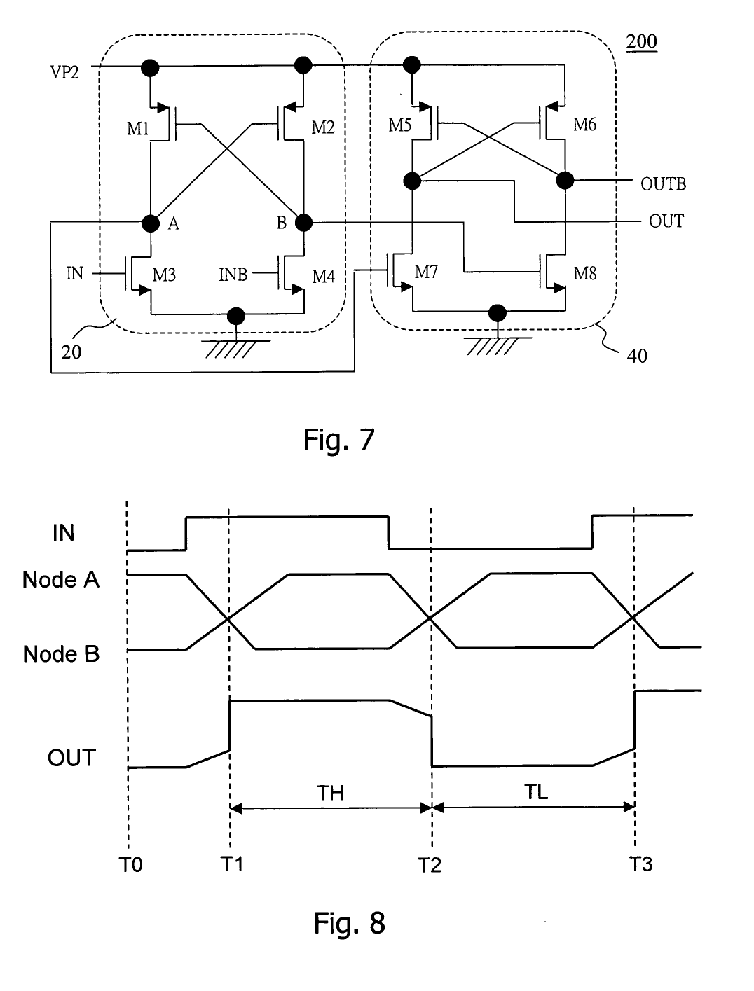

FIG. 7 schematically shows a second preferred embodiment according to the present invention. As shown in the figure, the level shift device 200 further comprises another level shift circuit 40 which includes a pair of PMOS transistors M5 and M6, and a pair of NMOS transistors M7 and M8. In the level shift circuit 40, the NMOS transistors M7 and M8 have the same width as that of the PMOS transistors M5 and M6. The level shift circuit 40 in this embodiment may be deemed as an equal-level shift circuit because its first operational voltage (the gate voltage of the transistors M7 and M8) is the same as its second operational voltage (its output), which are both 3.3V in this embodiment.

Referring to FIG. 8 in conjunction with FIG. 7, when the input IN switches from low to high, the voltage at the node A rapidly drops, while the voltage at the node B slowly increases. Correspondingly, the NMOS transistor M7 rapidly turns OFF but the NMOS transistor M8 slowly turns ON. Thus, the gate voltage of the PMOS transistor M5 drops slowly, and the output OUT of the overall circuit does not change state immediately. Only until the voltage at the node B is higher than that at the node A that the output OUT switches state to high, as referring to time T1.

Likely, when the input IN switches from high to low, the output OUT does not switch to low until the voltage at the node B is lower than that at the node A, as referring to time T2.

Thus, as seen from FIG. 8, the positive and negative duty cycles of the output OUT are the same, i.e., TH=TL, achieving the objectives of the present invention.

The features, characteristics and effects of the present invention have been described with reference to its preferred embodiments, for illustrating the spirit of the invention and not for limiting the scope of the invention. Various other substitutions and modifications will occur to those skilled in the art, without departing from the spirit of the present invention. For example, there are various ways to determine the overall output OUT according to the relationship between the voltages at the node A and node B, and these variations should all belong to the scope of the present invention. As another example, in each of the described embodiments, the level shift device is for converting a low voltage level to a high voltage level, but the present invention may be applied to a level shift circuit for high-to-low level shift as well. Therefore, all such substitutions and modifications are intended to be embraced within the scope of the invention as defined in the appended claims.

What is claimed is:

1. A level shift device, comprising:
a first level shift circuit for converting an input signal with a first voltage level to a first signal and a second signal with a second voltage level, wherein the first voltage level is different from the second voltage level, and the first signal and the second signal are substantially opposite in phase, and
an output stage circuit for generating an output signal according to the relationship between the first signal and the second signal, wherein the output signal includes a first value and a second value.

2. The level shift device of claim 1, wherein the input signal includes a first value and a second value, and the first value and the first voltage level are substantially the same.

3. The level shift device of claim 1, wherein the first signal and the second signal includes a third value and a forth value, the third values of the first signal and the second signal are substantially the same as the second voltage level, and the third value is different from the forth value.

4. The level shift device of claim 1, wherein the output signal is at the first value when the first signal is higher than the second signal, and the output signal is at the second value when the first signal is lower than the second voltage.

5. The level shift device of claim 1, wherein the first value of the output signal is substantially the same as the second voltage level.

6. The level shift device of claim 1, wherein the output stage circuit includes a comparator, and the comparator receives and compares the first signal and second signal to generate the output signal.

7. The level shift device of claim 1, wherein the output stage circuit includes a second level shift circuit, and the second level shift circuit is substantially the same as the first level shift circuit, which receives and converts the first signal and second signal to a first converted signal and a second converted signal, and outputs one of the first converted signal and the second converted signal as the output signal.

8. The level shift device of claim 7, wherein the second level shift circuit comprises a pair of PMOS transistors and a pair of NMOS transistors, each of the PMOS transistors having a drain electrically connected with a gate of the other PMOS transistor, and each of the NMOS transistors having a source electrically connected to ground, a drain electrically connected with the drain of one of the PMOS transistors, and a gate, and wherein gates of the pair of NMOS transistors receives the first signal and the second signal respectively.

9. A device for shifting voltage level, comprising:
a first level shift circuit for receiving an input signal with a first voltage level and converting the input signal to a first signal and a second signal with a second voltage level, wherein the first voltage is different from the second voltage, and the first signal and the second signal are substantially opposite in phase, and
an output circuit, coupled to the first level shift circuit, for generating an output signal according to the relationship between the first signal and the second signal, wherein the output signal includes a first value and a second value.

10. The device of claim 9, wherein the input signal has a third value and a fourth value, and the third value is substantially the same as the first voltage level.

11. The device of claim 9, wherein the first and second signals have a fifth value and a sixth value, respectively, and the fifth values of the first and second signals are substantially the same as the second voltage level.

12. The device of claim 9, wherein when the first signal is higher than the second signal, the output signal is high; when the first signal is lower than the second signal, the output signal is low, and wherein the first value of the output signal is substantially the same as the second voltage level.

13. The device of claim 9, wherein the output circuit is a comparator or a second level shift circuit.

14. The device of claim 9, wherein the first level shift circuit comprises:
a first transistor having a source coupled to an operational voltage with the second voltage level;
a second transistor having a source coupled to the operational voltage with the second voltage level;
a third transistor having a source receiving an operational voltage with the first voltage level, and a drain coupled to a drain of the first transistor and a gate of the second transistor; and
a fourth transistor having a source receiving the operational voltage with the first voltage level, and a drain coupled to a drain of the second transistor and a gate of the first transistor,
wherein the gates of the third and fourth transistors are for receiving signals and the drains of the first and second transistors are for outputting signals.

15. A method for shifting voltage level, comprising:
receiving an input signal with a first voltage level;
converting the input signal to a first signal and a second signal with a second voltage level, wherein the first voltage level is different from the second voltage level, and the first signal and the second signal are substantially opposite in phase, and
generating an output signal according to the relationship of the voltage levels of the first signal and the second signal, wherein the output signal includes a first value and a second value.

16. The method of claim 15, wherein the step of generating the output signal comprises:
comparing the voltage levels of the first signal and the second signal to generate the output signal.

17. The method of claim 15, wherein the second voltage level is higher than the first voltage level.

18. The method of claim 15, wherein the input signal comprises a third value and a fourth value, and the third value is substantially the same as the first voltage level.

19. The method of claim 15, wherein the first and second signals comprises a fifth value and a sixth value, and the fifth values of the first and second signals are substantially the same as the second voltage level.

20. The method of claim 15, wherein when the first signal is higher than the second signal, the output signal is high;
when the first signal is lower than the second signal, the output signal is low, and wherein the first value of the output signal is substantially the same as the second voltage level.
